(19) United States
(12) Patent Application Publication
(10) Pub. No.: US 2021/0408504 A1
(43) Pub. Date: Dec. 30, 2021

(54) DISPLAY PANEL AND PREPARATION METHOD THEREOF

(71) Applicant: SHENZHEN CHINA STAR OPTOELECTRONICS SEMICONDUCTOR DISPLAY TECHNOLOGY CO., LTD, Shenzhen (CN)

(72) Inventors: Jing GENG, Shenzhen (CN); Jun HOU, Shenzhen (CN)

(73) Assignee: SHENZHEN CHINA STAR OPTOELECTRONICS SEMICONDUCTOR DISPLAY TECHNOLOGY CO., LTD, Shenzhen (CN)

(21) Appl. No.: 16/618,374

(22) PCT Filed: Aug. 16, 2019
(86) PCT No.: PCT/CN2019/100923

§ 371 Date: Dec. 1, 2019

(30) Foreign Application Priority Data
Jun. 24, 2019 (CN) 201910549265.X

(51) Int. Cl. H01L 51/56; H01L 27/32

(52) U.S. Cl. CPC H01L 51/56; H01L 2227/323; H01L 27/3283; H01L 27/3246

(57) ABSTRACT

A display panel and a preparation method thereof are provided, the display panel includes a substrate, a pixel defining layer and a nano-columnar structure. The method includes a substrate providing step, a coating step, a drying step, a baking step, a cooling step, an exposure step, a developing step, a cleaning step, a high temperature curing step and a dry etching step. Performing a dry etching to the pixel defining layer by a mixed gas of carbon tetrafluoride and argon to form a nano-columnar structure on a surface of the pixel defining layer so that a surface roughness of the pixel defining layer is increased, and a surface lyophobic performance of the pixel defining layer is enhanced. Therefore, a film layer formed after an inkjet printing process has good uniformity and height. In addition, it effectively avoids “ink shrinkage” phenomenon, saves materials, increases productivity, and ensures good display effect.

### FIELD OF INVENTION

The present invention relates to the field of display, and in particular to a display panel and a method of preparing the same.

### BACKGROUND OF INVENTION

Currently, inkjet printing technology has been widely used in the preparation of display devices, such as the preparation of organic light-emitting layers in organic light-emitting diode (OLED) devices, color photoresist layers in quantum dot color filter substrates, etc., which are all patterned by the inkjet printing technology. In order to enable ink to be printed to a designated area and to form a shape of sub-pixel, it is necessary to provide a pixel defining layer on a substrate. The pixel defining layer is composed of a plurality of dams arranged in equal intervals. A groove is formed between the two adjacent dams and the substrate. When performing inkjet printing to form the pixel defining layer, the ink is first printed to a bottom of the groove, the groove is slowly filled by the ink, and the ink is cured to form a film layer.

As shown in FIG. 1, in an ideal state, a height of the film layer 200 is greater than a height of the pixel defining layer 2. The ink is cured and forming the film layer is to fill the groove. A surface of the film layer 200 is curved and its middle portion is convex.

As shown in FIG. 2, in the prior art, a height of the film layer 200 formed after the inks are solidified tends to be lower than a height of the pixel defining layer 2, thereby causing the film layer 200 to exhibit an “ink shrinkage” phenomenon, wherein, a surface of the film layer 200 is linear, and its middle portion is concave. The reason is that a surface of the pixel defining layer 2 is relatively smooth, and a rolling angle of the ink is large, thereby affecting the hydrophobic property of the surface of the pixel defining layer 2. If repeatedly perform inkjet printing to the groove, may be causing the film layer 200 unevenly distributed, and wasting the material, thereby affecting the productivity and display quality.

### Technical Problem

An object of the present invention is to provide a display panel and a method of preparing the same to solve the technical problem of “ink shrinkage” phenomenon in the prior art. It affects the uniformity of the film layer and the display quality of the display after the ink is printed and cured to form a pixel defining layer.

### SUMMARY OF INVENTION

In order to solve the above problems, the present invention provides a display panel including a substrate, a pixel defining layer, and a nano-columnar structure, wherein the pixel defining layer is disposed on an upper surface of the substrate, and the nano-columnar structure protrudes from an upper surface of the pixel defining layer.

Further, a ratio of a height of the pixel defining layer to a height of the nano-columnar structure ranges between 10 and 100.

Further, the nano-columnar structure includes at least three nano-pillars.

Further, a diameter of each of the nano-pillars ranges between 15 nm and 50 nm.

In order to solve the above problems, the present invention further provides a method for preparing a display panel, including a dry etching step of dry etching a pixel defining layer by using a mixed gas of carbon tetrafluoride and argon. A nano-columnar structure is formed on a surface of the pixel defining layer.

Further, the dry etching step specifically includes: a substrate feeding step and the substrate provided with the pixel defining layer is fed into a reactor; a gas introduction step, introducing a mixed gas of carbon tetrafluoride and argon into the reactor; a reaction step, performing a dry etching treatment on the pixel defining layer to form the nano-columnar structure on the surface of the pixel defining layer; and a substrate taking out step, taking out the substrate from the reactor.

Further, in the substrate feeding step, the reactor is a capacitively coupled plasma reactor. In the gas introduction step, a flow ratio of the carbon tetrafluoride to the argon ranges between 2 and 3. The gas pressure in the reactor ranges between 30 millitorr and 200 millitorr; and in the reaction step, a dry etching treatment time ranges between 60 seconds and 120 seconds.

Further, before the dry etching step, further includes: a substrate feeding step to provide the substrate; a coating step, coating a surface of the substrate with a photoresist solution to form a photoresist layer; a drying step, performing a drying treatment to the photoresist layer; a baking step, performing a baking treatment to the substrate; a cooling step, performing a cooling treatment to the substrate; an exposure step, performing an exposure treatment using a photomask to the photoresist layer; a developing step, performing a developing treatment to the photoresist layer with an alkaline developing solution to form the pixel defining layer; a cleaning step, performing a cleaning treatment to the substrate and the pixel defining layer; and a high temperature curing step, performing a high temperature curing treatment to the pixel defining layer.

Further, in the coating step, the photoresist solution is a negative photoresist solution; in the drying step, placing the photoresist layer in a vacuum drying chamber; in the baking step, placing the substrate on a hot plate at 88-92° C., and performing a heat treatment to the substrate for 88-92 seconds; and in the cooling step, placing the substrate on a cold plate at 20-25° C., and performing the cooling treatment to the substrate for 58-62 seconds.

Further, in the high temperature curing step, placing the pixel defining layer to an environment of 220-240° C. to perform a high temperature curing treatment for 58-62 seconds.

### Beneficial Effect

The technical effect of the present invention is to provide a display panel and a method for preparing the same, which includes performing a dry etching process to a pixel defining layer by using a mixed gas of carbon tetrafluoride and argon to form a nano-columnar structure on a surface of the pixel defining layer, such that a surface roughness of the pixel defining layer is increased, and a surface lyophobic performance of the pixel defining layer is enhanced. Therefore, a film layer formed after an inkjet printing process has good uniformity and height. In addition, it effectively avoids the phenomenon of “ink shrinkage”, saves materials, increases productivity, and ensures a good display effect.

### DESCRIPTION OF DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a schematic structural view showing an ideal structure of a film layer.

FIG. 2 is a schematic structural view showing a phenomenon of “ink shrinkage” of a film layer in the prior art.

FIG. 3 is a schematic structural view of a nano-columnar structure of the present invention.

FIG. 4 is a flowchart of a method for preparing a display panel of the present invention.

FIG. 5 is a schematic structural view of a photoresist layer of the present invention.

FIG. 6 is a schematic structural view of an exposed photoresist layer of the present invention.

FIG. 7 is a schematic structural diagram of a pixel defining layer of the present invention.

FIG. 8 is a flowchart of a dry etching step of the present invention.

FIG. 9 is a schematic structural view showing a contact angle θ1 between a surface of the pixel defining layer of the prior art and the ink.

FIG. 10 is a structural schematic view showing a contact angle θ2 between a surface of the pixel defining layer of the present invention and the ink.

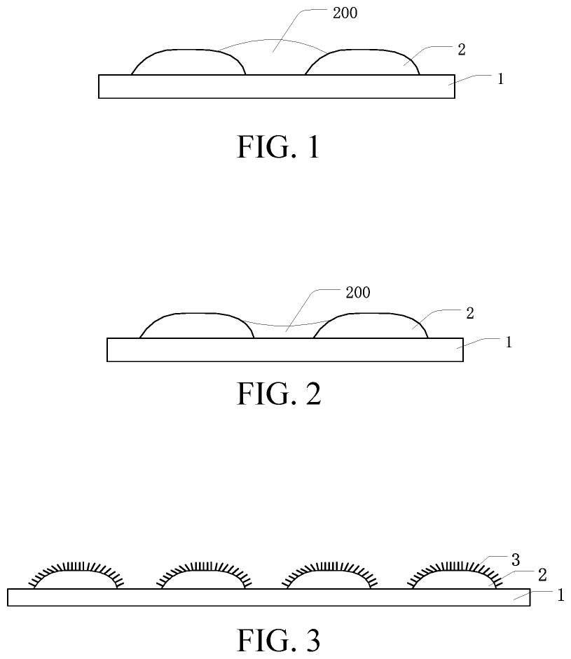

The reference numerals in the drawings are as follows: substrate 1; pixel defining layer 2; nano-columnar structure 3; photoresist layer 100; film layer 200; ink 300.

### DETAILED DESCRIPTION OF PREFERRED EMBODIMENTS

The preferred embodiments of the present invention are described below with reference to the accompanying drawings. The drawings are used to exemplify the embodiments of the present invention and fully describe the technical contents of the present invention to make the present invention clearer and easy to understand. However, the invention may be embodied in many different forms of embodiments, and the scope of the invention is not limited to the embodiments set forth herein.

The embodiment provides a display panel and a method for preparing the display panel, which will be separately described in detail as follows.

As shown in FIG. 3, the display panel includes a substrate 1, a pixel defining layer 2, and a nano-columnar structure 3. The substrate 1 is a glass substrate of the prior art. An upper surface of the substrate 1 is provided with a pixel defining layer 2, and an upper surface of the pixel defining layer 2 is provided with a protruding nano-columnar structure 3, which roughens the upper surface of the pixel defining layer 2. In the embodiment, a ratio of a height of the pixel defining layer 2 to a height of the nano-columnar structure 3 is 10-100. The nano-columnar structure 3 includes three or more nano-pillars each having a diameter of 15-50 nm.

A protruding nano-columnar structure 3 is disposed on a surface of the pixel defining layer 2. When performing an inkjet printing process, the ink penetrates into the nano-columnar structure 3 and then contacts the pixel defining layer 2, which increases a contact surface between the ink and the surface of the pixel defining layer 2. A contact angle of the ink with the surface of the pixel defining layer 2 is larger, thereby enhancing a surface lyophobic performance of the pixel defining layer 2. Therefore, the height of the film formed by the ink after curing is greater than the height of the pixel defining layer. An upper surface of the film layer has an arc shape, which has good uniformity, thereby effectively avoids the phenomenon of “ink shrinkage”, saves materials, improves production capacity, and ensures good display effect.

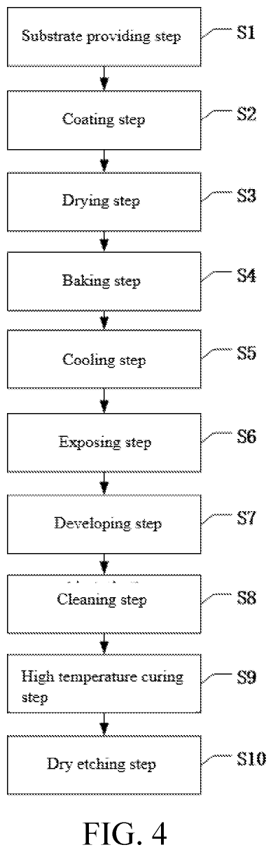

As shown in FIG. 4, the embodiment further provides a method for preparing a display panel, including step S1-S9.

Step S1: a substrate providing step, providing a clean and dry substrate 1.

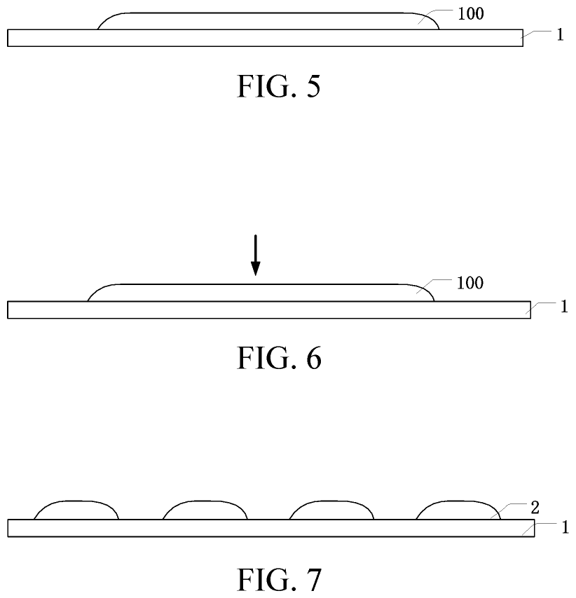

Step S2: a coating step, uniformly applying a negative photoresist solution to the clean and dry substrate 1 by a doctor blade to form a photoresist layer 100, as shown in FIG. 5.

Step S3: a drying step, placing the photoresist layer 100 in a vacuum drying chamber, and subjecting the photoresist layer 100 to a low-pressure drying treatment.

Specifically, a boiling point of a solvent in the photoresist layer is reduced under the low-pressure environment. The solvent can quickly escape a surface of the photoresist layer, thereby most of the solvent is removed. Thus, in the subsequent process, a sudden boiling phenomenon of the solvent in the photoresist layer can be prevented. In addition, during the handling process, the photoresist solvent in the photoresist layer is prevented from flowing to cause display unevenness, which affects the yield of the display panel.

Step S4: a baking step, the substrate 1 is placed on a hot plate at 88-92° C., and the substrate 1 is baked for 88-92 seconds to further evaporate the photoresist solvent in the photoresist layer.

Specifically, a function of the hot plate is to further evaporate the solvent remaining in the photoresist layer and to activate a photosensitizer in a photoresist by heating to enhance its photosensitivity. The baking time in the embodiment is preferably 90 seconds.

Step S5: a cooling step, the substrate is placed on a cold plate at 20-25° C., and the substrate is subjected to a cooling treatment for 58-62 seconds. In the embodiment, the cooling treatment time is preferably 60 seconds.

Step S6: an exposure step, subjecting the photoresist layer 100 to an exposure treatment using a photomask, as shown in FIG. 6. Specifically, the photoresist layer is exposed to light using the photomask. The photomask has a light transmitting area and a non-light transmitting area. Under ultraviolet irradiation, a portion of the photoresist layer corresponding to the light transmitting area is an exposure area, and a portion of the photoresist layer corresponding to the non-light transmitting area is a non-exposure area.

In the embodiment, a portion of the photoresist layer (exposure area) corresponding to the light-transmitting area undergoes a chemical reaction under an irradiation of the ultraviolet light. The photoresist layer includes a solvent, a dispersant, a polymer, a monomer, a photo initiator, and a pigment. The photoresist layer is irradiated by the ultraviolet light, wherein the photo initiator decomposes to generate free radicals to open the double bonds of the monomers and the polymers, thereby causing a crosslinking reaction to form a network. A film layer structure which is not easily soluble in an alkaline developing solution is formed. However, a portion of the photoresist layer corresponding to the non-light transmitting area is not irradiated by the ultraviolet light, such that no crosslinking reaction occurs.

Step S7: a developing step: subjecting the photoresist layer to a developing treatment with an alkaline developing solution to form a pixel defining layer 2, as shown in FIG. 7.

The alkaline developing solution is sprayed uniformly onto the photoresist layer by spraying. The unexposed photoresist layer can be dissolved by reacting with the alkaline developing solution, and the exposed photoresist layer is insoluble in the alkaline developing solution, and thereby remains on the substrate to form the pixel defining layer. In addition, in order to make the photoresist layer be formed more uniform, those skilled in the art may spray the substrate by tilting the substrate at an angle of 15°. In the present embodiment, the alkaline developing solution is preferably potassium hydroxide.

Step S8: a cleaning step, using deionized water to clean the developing solution remaining on the substrate and the pixel defining layer. After the cleaning step, the moisture on the substrate and the surface of the pixel defining layer can be dried by an air knife.

Step S9: a high temperature curing step, wherein the pixel defining layer is subjected to a high-temperature treatment for 58-62 seconds under an environment of 220-240° C., such that the pixel defining layer is cured.

Step S10: a dry etching step, performing a dry etching treatment by a mixed gas of carbon tetrafluoride and argon to the pixel defining layer 2 to form a nano-columnar structure 3 on a surface of the pixel defining layer 2, as shown in FIG. 3.

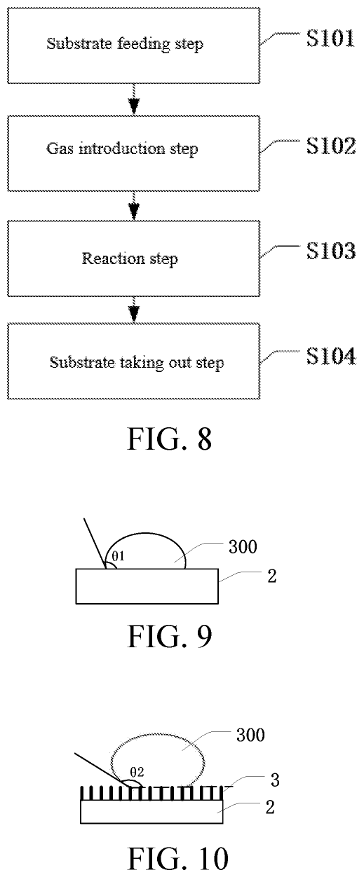

Steps S101-S104 are further included in the Step S10 (dry etching step), as shown in FIG. 8.

S101: a substrate feeding step, feeding a substrate provided with the pixel defining layer into a reactor, the reactor is a capacitively coupled plasma reactor.

S102: a gas introduction step, a flow ratio of the carbon tetrafluoride to the argon ranges between 2 and 3, and the gas pressure in the reactor ranges between 30 millitorr and 200 millitorr; and in the reaction step, a dry etching treatment time ranges between 60 seconds and 120 seconds.

S103: a reaction step, performing the dry etching treatment on the pixel defining layer to form a nano-columnar structure on a surface of the pixel defining layer.

S104: a substrate taking out step, taking out the substrate from the reactor.

Specifically, a capacitively coupled plasma reactor is used to enhance an etching of the capacitively coupled plasma during the reaction. An upper electrode (anode) of the capacitively coupled plasma reactor is grounded, and an RF excitation source (13.56 MHz) and a low-frequency excitation source (3.2 MHz) are applied to a lower electrode. The substrate and the pixel defining layer are placed on the lower electrode, and the etching source are ions and active groups generated in the plasma region. The ions generated in the plasma are incident perpendicularly to the pixel defining layer under an effect of the electric field. The etching to an etched object is mainly by bombardment i.e. a physical etching, and its etching characteristic is anisotropic. At the same time, the active group etches an etched object mainly by chemical reactive etching, and its etching characteristic is isotropic, thereby, the damage to a surface of the film is minor.

In the embodiment, the etching gas is preferably carbon tetrafluoride and argon. The gas flow rate is preferably 500 (standard cubic centimeter per minute, sccm) of carbon tetrafluoride and 200 sccm of argon gas. A gas pressure of the chamber is 30-200 millitorr, preferably 40 millitorr, 80 millitorr, 100 millitorr, 125 millitorr, 155 millitorr, 180 millitorr, 188 millitorr, and 190 millitorr. The input power is 4000 W for the RF excitation source and 2000 W for the low-frequency excitation source. The etching time is 60-120 seconds, preferably 72 seconds, 88 seconds, 96 seconds, 110 seconds, and 117 seconds.

In the prior art, wettability of a surface of a solid is determined by its chemical composition and three-dimensional microstructure of the surface of the solid. The wettability of a droplet on the surface of the solid is generally described by Young's equation: cos θ=(γₛᵥ−γₛₗ)/γₗᵥ, where γₛᵥ, γₛₗ, and γₗᵥ each denotes an interfacial tension between solid and gas, solid and liquid, and gas and liquid, respectively. θ is a contact angle when the gas phase, liquid phase, and solid phase are in phase equilibrium. It exhibits a hydrophobic property when θ>90°, and it exhibits a hydrophilic property when θ<90°.

Generally, there are two ways to enhance the contact angle and the lyophobic performance of the solid surface. One is to reduce the surface free energy of the solid by chemical methods. Currently, known hydrophobic materials, silicones, and organic fluorine materials have low surface free energies, wherein the surface free energies of the fluorine-containing groups decrease in orders of —CH₂, —CH₃, —CF₂, C—F₂H, and —CF₃. The other way is to increase the roughness of the solid surface.

In the embodiment, the purpose for using carbon tetrafluoride as etching gas is that the carbon tetrafluoride not only can serve as an etching gas for the pixel defining layer to improve the roughness of the surface of the pixel defining layer but also can fluorinate a surface of the pixel defining layer, and to form a nano-columnar structure on the surface of the pixel defining layer. Thus, it enhancing the lyophobic performance of the surface of the pixel defining layer by the two aspects.

During the etching process, a surface of the pixel defining layer is fluorinated and the nano-columnar structure is formed thereon. First, a mixed gas of carbon tetrafluoride and argon bombards the pixel defining layer and the substrate, the pixel defining layer is etched over its entire surface. Because the substrate is a glass substrate, a portion of SiO₂ in the glass is transferred to the surface of the pixel definition layer. At the same time, a —CF₂— group of the carbon tetrafluoride enables the double bonds of the monomer and the polymer in the pixel defining layer to be opened and crosslinked therewith. Thus, it functions to fluorinate the surface of the photoresist, reduce the free energy of the surface of the pixel defining layer and improve its lyophobic performance.

Following, the SiO₂ transferred to the surface of the pixel defining layer becomes a “Hard Mask” for etching the photoresist. As the etching proceeds, the velvet-like nano-columnar structure is formed on the surface of the pixel defining layer. The formation of the nano-columnar structure will greatly increase the roughness of the surface of the pixel defining layer.

As shown in FIG. 9, in the prior art, the surface of the pixel defining layer 2 is relatively smooth, the ink 300 dropped on the surface of the pixel defining layer is easily moved, thereby the ink 300 is prone to occur “ink shrinkage” phenomenon after curing. The ink 300 has stronger wettability on the surface of the relatively smooth pixel defining layer 2, such that reducing the contact surface of the ink 300 with the pixel defining layer 2. The ink 300 forms a contact angle designated as θ1 with the surface of the relatively smooth pixel defining layer 2.

As shown in FIG. 10, in the embodiment, a surface of the pixel defining layer 2 is relatively rough, the ink 300 dropped on the surface of the pixel defining layer 2 is not easily moved. The ink 300 forms a film layer after curing and has good uniformity and height. The reason is that the upper surface of the pixel defining layer 2 is provided with a nano-columnar structure 3. The nano-columnar structure 3 has a concave-convex structure. The ink 300 penetrates into the nano-columnar structure 3 and then contacts the pixel defining layer 2, thereby increasing the contact area of the ink 300 with the pixel defining layer 2. The ink 300 forms a contact angle designated as 02 on the surface of the relatively rough pixel defining layer 2.

Therefore, the contact angle θ1 is larger than the contact angle θ2. In the embodiment, the contact angle θ2 of the ink with the pixel defining layer is increased, and the rolling angle of the ink with the surface of the pixel defining layer is decreased, that is, the hydrophobic property of the surface of the pixel defining layer is enhanced. This is the same principle as the superhydrophobic property of the surface of lotus leaf and the surface of Cicada's wings.

As shown in FIG. 9 and FIG. 10, the contact angle θ1 of the ink 300 formed on the surface of the relatively smooth pixel defining layer 2 is much smaller than the contact angle θ2 of the ink 300 formed on the surface of the relatively rough pixel defining layer 2. The smaller the contact angle, the worse the wettability, such that the ink is easier to move on the surface. Thus, after forming a nano-columnar structure 3 on a surface of the pixel defining layer 2 by dry etching, the roughness of a surface of a pixel defining layer 2 is increased, such that the hydrophobic property of the pixel defining layer 2 is enhanced. Therefore, the film layer formed after the inkjet printing process has good uniformity and height. Therefore, it effectively avoids the “ink shrinkage” phenomenon, saves materials, increases productivity, and ensures a good display effect.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A display panel, comprising:
a substrate;
a pixel defining layer disposed on an upper surface of the substrate; and
a nano-columnar structure protruding from an upper surface of the pixel defining layer.

2. The display panel according to claim 1, wherein a ratio of a height of the pixel defining layer to a height of the nano-columnar structure ranges between 10 and 100.

3. The display panel according to claim 1, wherein the nano-columnar structure comprises at least three nano-pillars.

4. The display panel according to claim 3, wherein a diameter of each of the nano-pillars ranges between 15 nm and 50 nm.

5. A method of preparing a display panel, comprising:
a dry etching step, performing a dry etching treatment using a mixed gas of carbon tetrafluoride and argon to a pixel defining layer to form a nano-columnar structure on a surface of the pixel defining layer.

6. The method of preparing the display panel according to claim 5, wherein the dry etching step further comprises:
a substrate feeding step, feeding a substrate provided with the pixel defining layer into a reactor;
a gas introduction step, introducing the mixed gas of carbon tetrafluoride and argon into the reactor;
a reaction step, performing the dry etching treatment on the pixel defining layer to form the nano-columnar structure on the surface of the pixel defining layer; and
a substrate taking out step, taking out the substrate from the reactor.

7. The method of preparing the display panel according to claim 6, wherein in the substrate feeding step, the reactor is a capacitively coupled plasma reactor;
in the gas introduction step, a flow ratio of the carbon tetrafluoride to the argon ranges between 2 and 3, and a gas pressure in the reactor ranges between 30 millitorr and 200 millitorr; and
in the reaction step, a dry etching treatment time ranges between 60 seconds and 120 seconds.

8. The method of preparing the display panel according to claim 5, wherein prior to the dry etching step, the method further comprises:
a substrate providing step, providing a substrate;
a coating step, coating a surface of the substrate with a photoresist solution to form a photoresist layer;
a drying step, performing a drying treatment to the photoresist layer;
a baking step, performing a baking treatment to the substrate;
a cooling step, performing a cooling treatment to the substrate;
an exposure step, performing an exposure treatment using a photomask to the photoresist layer;
a developing step, performing a developing treatment to the photoresist layer with an alkaline developing solution to form the pixel defining layer;
a cleaning step, performing a cleaning treatment to the substrate and the pixel defining layer; and
a high temperature curing step, performing a high temperature curing treatment to the pixel defining layer.

9. The method of preparing the display panel according to claim 8, wherein in the coating step, the photoresist solution is a negative photoresist solution;
in the drying step, placing the photoresist layer in a vacuum drying chamber; in the baking step, placing the substrate on a hot plate at 88-92° C., and performing a heat treatment to the substrate for 88-92 seconds; and
in the cooling step, placing the substrate on a cold plate at 20-25° C., and performing the cooling treatment to the substrate for 58-62 seconds.

10. The method of preparing the display panel according to claim 8, wherein in the high temperature curing step, placing the pixel defining layer to an environment of 220-240° C. to perform a high temperature curing treatment for 58-62 seconds.
